(19) United States
(12) Patent Application Publication
(10) Pub. No.: US 2024/0266327 A1
(43) Pub. Date: Aug. 8, 2024

(54) ELECTRONIC DEVICE

(71) Applicant: InnoLux Corporation, Miao-Li County (TW)

(72) Inventors: Yu-Siou LIN, Miao-Li County (TW); Ting-Ying WU, Miao-Li County (TW); Yang-Ruei LI, Miao-Li County (TW)

(21) Appl. No.: 18/403,986

(22) Filed: Jan. 4, 2024

(30) Foreign Application Priority Data
Feb. 7, 2023 (CN) 202310095185.8

(51) Int. Cl. H01L 25/075

(52) U.S. Cl. CPC H01L 25/0753; G02F 1/133603

(57) ABSTRACT

An electronic device includes a light-emitting module including a substrate, a plurality of light-emitting units, and a light-adjusting layer. The substrate has a first region and a second region, the second region being closer to the edge of the substrate than the first region. The light-emitting units are disposed on the substrate, wherein the light-emitting units include a first light-emitting unit disposed in the first region and a second light-emitting unit disposed in the second region. The light-adjusting layer includes a first light-adjusting element disposed on the first light-emitting unit and a second light-adjusting element disposed on the second light-emitting unit. The first light-adjusting element and the second light-adjusting element have different dimensions.

### CROSS REFERENCE TO RELATED APPLICATIONS

This application claims priority of China Patent Application No. 2023100951858, filed on Feb. 7, 2023, the entirety of which is incorporated by reference herein.

### BACKGROUND

### Technical Field

The present disclosure relates to an electronic device, and in particular it relates to an electronic device with light-adjusting elements of different dimensions arranged on a substrate.

### Description of the Related Art

Using traditional technology, a light board is coated with ink to optimize the graininess of in-plane visual effects. However, ink-printed light boards cause loss of light due to the ink. When the distance between light sources is greater, the problem with there being shadows around the display panel becomes more serious.

### SUMMARY

In accordance with one embodiment of the present disclosure, an electronic device is provided. The electronic device includes a light-emitting module. The light-emitting module includes a substrate, a plurality of light-emitting units, and a light-adjusting layer. The substrate has a first region and a second region, the second region being closer to the edge of the substrate than the first region. The light-emitting units are disposed on the substrate, wherein the light-emitting units include a first light-emitting unit disposed in the first region and a second light-emitting unit disposed in the second region. The light-adjusting layer includes a first light-adjusting element disposed on the first light-emitting unit and a second light-adjusting element disposed on the second light-emitting unit. The first light-adjusting element and the second light-adjusting element have different dimensions.

A detailed description is given in the following embodiments with reference to the accompanying drawings.

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIG. 1 shows a cross-sectional view of an electronic device in accordance with one embodiment of the present disclosure;

FIG. 2A shows a top view of an electronic device in accordance with one embodiment of the present disclosure;

FIG. 2B shows a top view of an electronic device in accordance with one embodiment of the present disclosure;

FIG. 2C shows a top view of an electronic device in accordance with one embodiment of the present disclosure;

FIG. 2D shows a top view of an electronic device in accordance with one embodiment of the present disclosure;

FIG. 3 shows a cross-sectional view of an electronic device in accordance with one embodiment of the present disclosure;

FIG. 4 shows a cross-sectional view of an electronic device in accordance with one embodiment of the present disclosure.

### DETAILED DESCRIPTION

Various embodiments or examples are provided in the following description to implement different features of the present disclosure. The elements and arrangement described in the following specific examples are merely provided for introducing the present disclosure and serve as examples without limiting the scope of the present disclosure. For example, when a first component is referred to as “on a second component”, it may directly contact the second component, or there may be other components in between, and the first component and the second component do not come in direct contact with one another.

It should be understood that additional operations may be provided before, during, and/or after the described method. In accordance with some embodiments, some of the stages (or steps) described below may be replaced or omitted.

In this specification, spatial terms may be used, such as “below”, “lower”, “above”, “higher” and similar terms, for briefly describing the relationship between an element relative to another element in the figures. Besides the directions illustrated in the figures, the devices may be used or operated in different directions. When the device is turned to different directions (such as rotated 45 degrees or other directions), the spatially related adjectives used in it will also be interpreted according to the turned position. In addition, in this specification, expressions such as “first material layer disposed above/on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer. In some embodiments of the present disclosure, terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Herein, the terms “about”, “around” and “substantially” typically mean a value is in a range of +/−15% of a stated value, typically a range of +/−10% of the stated value, typically a range of +/−5% of the stated value, typically a range of +/−3% of the stated value, typically a range of +/−2% of the stated value, typically a range of +/−1% of the stated value, or typically a range of +/−0.5% of the stated value. The stated value of the present disclosure is an approximate value. Namely, the meaning of “about”, “around” and “substantially” still exists even if there is no specific description of “about”, “around” and “substantially”.

It should be understood that, although the terms “first”, “second”, “third”, etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, portion or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

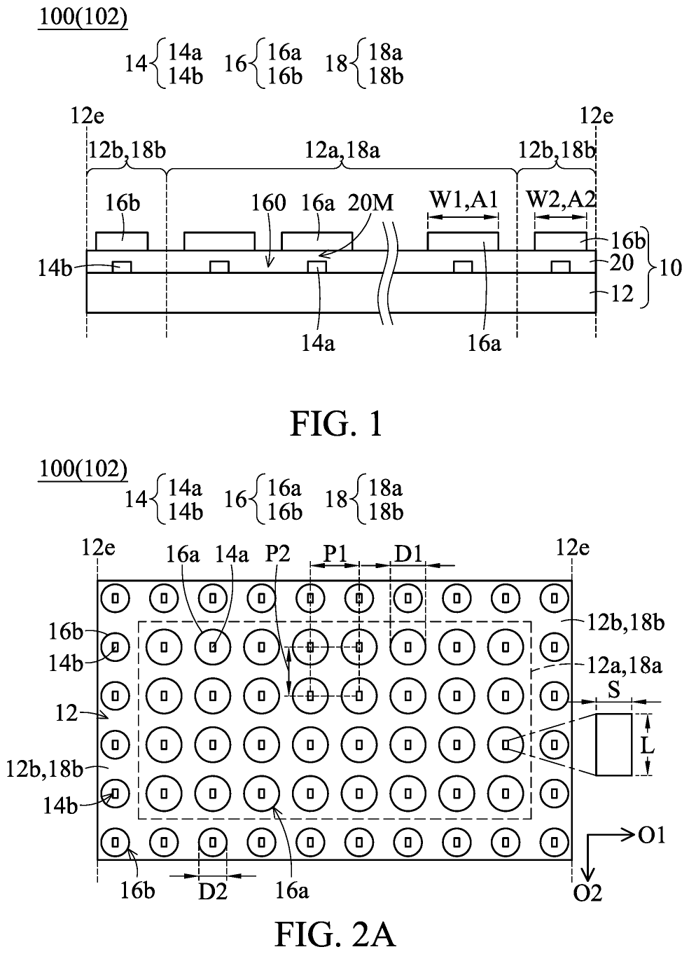

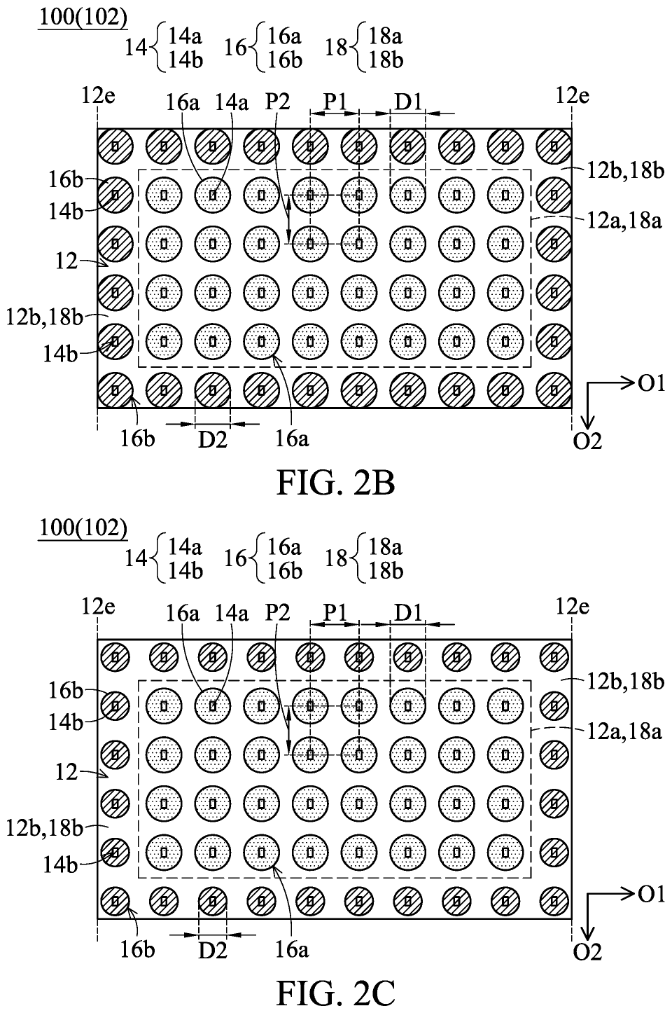

Referring to FIGS. 1 and 2A, in accordance with one embodiment of the present disclosure, an electronic device 100 is provided. FIG. 1 is a cross-sectional view of the electronic device 100. FIG. 2A is a top view of the electronic device 100.

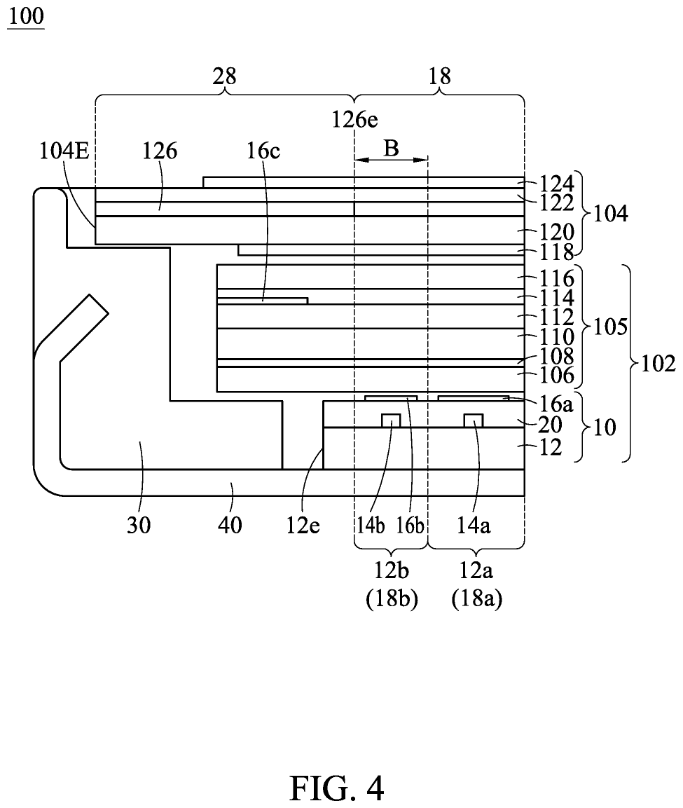

As shown in FIGS. 1 and 2A, and referring to FIG. 4, the electronic device 100 includes a light-emitting module 102. The light-emitting module 102 includes a light-emitting substrate 10 and an optical film 105. The optical film 105 is disposed on the light-emitting substrate 10 and located in the direction of light emission of the light-emitting substrate 10. The light-emitting substrate 10 includes a substrate 12, a plurality of light-emitting units 14, a light-adjusting layer 16, and an encapsulation layer 20. The substrate 12 has a first region 12a and a second region 12b. The second region 12b is closer to the edge 12e of the substrate 12 than the first region 12a. The first region 12a may be closer to the middle of the substrate 12. As shown in FIG. 2A, the second region 12b may surround the first region 12a, but the present disclosure is not limited thereto. The light-emitting units 14 are disposed on the substrate 12. The light-emitting units 14 include a first light-emitting unit 14a and a second light-emitting unit 14b. The first light-emitting unit 14a is disposed in the first region 12a. The second light-emitting unit 14b is disposed in the second region 12b. There may be multiple first light-emitting units 14a, and multiple second light-emitting units 14b, and the number is not limited. In accordance with some embodiments, the number of the first light-emitting units 14a in the first region 12a may be greater than the number of the second light-emitting units 14b in the second region 12b.

As shown in FIGS. 1 and 2A, the light-adjusting layer 16 includes a first light-adjusting element 16a and a second light-adjusting element 16b. The first light-adjusting element 16a is disposed on the first light-emitting unit 14a. The second light-adjusting element 16b is disposed on the second light-emitting unit 14b. There may be multiple first light-adjusting elements 16a, and multiple second light-adjusting elements 16b, and the number is not limited. In accordance with some embodiments, a single first light-adjusting element 16a may be correspondingly disposed on a single first light-emitting unit 14a. A single second light-adjusting element 16b may be correspondingly disposed on a single second light-emitting unit 14b, but the present disclosure is not limited thereto. In accordance with some embodiments, a single first light-adjusting element 16a may be correspondingly disposed on a plurality of first light-emitting units 14a. A single second light-adjusting element 16b may be correspondingly disposed on a plurality of second light-emitting units 14b. The first light-adjusting element 16a and the second light-adjusting element 16b have different dimensions. In accordance with some embodiments, a plurality of first light-adjusting elements 16a are disposed in the first region 12a, a plurality of second light-adjusting elements 16b are disposed in the second region 12b, and at least one of the plurality of first light-adjusting elements 16a and at least one of the plurality of second light-adjusting elements 16b have different dimensions. In accordance with some embodiments, at least some of the plurality of first light-adjusting elements 16a and at least some of the plurality of second light-adjusting elements 16b have different dimensions. In accordance with some embodiments, all the plurality of first light-adjusting elements 16a and all the plurality of second light-adjusting elements 16b have different dimensions.

As shown in FIG. 1, the encapsulation layer 20 may be disposed above the plurality of light-emitting units 14. In detail, in accordance with some embodiments, the encapsulation layer 20 may cover the plurality of light-emitting units 14 and fill in the gap 160 between the plurality of light-emitting units 14, for example, disposed in the gap 160 between two adjacent light-emitting units 14. At least part of the encapsulation layer 20 may be disposed between the plurality of light-emitting units 14 and the light-adjusting layer 16. For example, at least part of the encapsulation layer 20 (marked as 20M in the figure) is disposed between the first light-emitting unit 14a and the first light-adjusting element 16a of the light-adjusting layer 16. In accordance with some embodiments, the encapsulation layer 20 is continuously disposed above the plurality of light-emitting units 14 and disposed in the gap 160 between the plurality of light-emitting units 14. The material of the encapsulation layer 20 may be resin.

In some embodiments, the substrate 12 may include a rigid substrate or a flexible substrate. In some embodiments, the rigid substrate may include a silicon substrate or a glass substrate, but the present disclosure is not limited thereto, and other suitable rigid substrate materials are also applicable to the present disclosure. In some embodiments, the flexible substrate may include a polyimide (PI) substrate, a polyethylene terephthalate (PET) substrate, or a polycarbonate (PC) substrate, but the present disclosure is not limited thereto, and other suitable flexible substrate materials are also applicable to the present disclosure. As shown in FIG. 2A, in the substrate 12, the first region 12a and the second region 12b are adjacent, and the second region 12b surrounds the first region 12a. In accordance with some embodiments, the substrate 12 may be a circuit board, including a circuit (not shown) electrically connected to the plurality of light-emitting units 14. In accordance with some embodiments, the light-emitting units 14 may be light-emitting diodes (LEDs). The light-emitting unit 14 may include a P-type electrode and an N-type electrode. The P-type electrode and the N-type electrode may be electrically connected to bonding pads on the circuit board.

As shown in FIG. 4, the electronic device 100 has a display region 18 and a non-display region 28. In detail, the electronic device 100 may include a display panel 104 disposed above the light-emitting module 102. In accordance with some embodiments, the display panel 104 may be a liquid-crystal display panel. The display panel 104 is disposed on the light-emitting module 102 and located in the direction of light emission of the light-emitting module 102. The light-emitting module 102 may provide a light source for the liquid-crystal display panel. The display panel 104 has the display region 18 and the non-display region 28. The display region 18 includes a central region 18a and an edge region 18b, and the edge region 18b is closer to the edge 104E of the display panel 104. The display region 18 includes the first region 12a and the second region 12b of the substrate 12 in the light-emitting module 102. That is, the first region 12a and the second region 12b of the light-emitting module 102 correspond to the display region 18 of the display panel 104. For example, the first region 12a corresponds to the central region 18a of the display region 18, and the second region 12b corresponds to the edge region 18b of the display region 18. In accordance with some embodiments, in the display region 18, the display panel 104 may display images. In the non-display region 28, the display panel 104 does not display images. The display panel 104 may include a light-shielding layer 126. The light-shielding layer 126 may be disposed near the edge 104E of the display panel 104. The region corresponding to the light-shielding layer 126 may be the non-display region 28. The light-shielding layer 126 is, for example, a black matrix.

In some embodiments, the light-emitting units 14 (for example, the first light-emitting unit 14a and the second light-emitting unit 14b) serving as the light source of the electronic device 100 may be light-emitting diodes. For example, they may be submillimeter light-emitting diodes (mini LEDs), such as blue submillimeter light-emitting diodes (blue mini LEDs), but the present disclosure is not limited thereto, and other suitable light-emitting diodes are also applicable to the present disclosure. In some embodiments, the light-emitting unit 14 may be a rectangle with a long side L and a short side S, as shown in FIG. 2A, but the present disclosure is not limited thereto, and other suitable shapes of the light-emitting units are also applicable to the present disclosure. In some embodiments, when the light-emitting unit 14 is rectangular, its long side L may be in a range from about 0.1 mm to about 1 mm. For example, it is in a range from about 0.2 mm to about 0.8 mm, for example, in a range from about 0.3 mm to about 0.6 mm, but the present disclosure is not limited thereto, and other suitable dimensions of the light-emitting unit are also applicable to the present

### DISCLOSURE

In some embodiments, as shown in FIG. 2A, the multiple light-emitting units 14 may be disposed in an array. There are a first pitch P1 in a first direction O1 and a second pitch P2 in a second direction O2 between adjacent light-emitting units 14. In some embodiments, the first direction O1 may be a horizontal direction, and the second direction O2 may be a vertical direction. In some embodiments, the first pitch P1 and the second pitch P2 may be, for example, in a range from about 2 mm to about 7 mm. For example, they are in a range from about 4 mm to about 6 mm, for example, in a range from about 4.5 mm to about 5.5 mm, but the present disclosure is not limited thereto, and other suitable pitch dimensions of the light-emitting units are also applicable to the present disclosure. In accordance with some embodiments, the first pitch P1 and the second pitch P2 may be the same. In accordance with some embodiments, the first pitch P1 and the second pitch P2 may be different, for example, the first pitch P1 may be greater than the second pitch P2, for example, the first pitch P1 may be smaller than the second pitch P2.

In some embodiments, the light-adjusting layer 16 (e.g., the first light-adjusting element 16a and the second light-adjusting element 16b) is ink, e.g., white ink, but the present disclosure is not limited thereto, and other suitable materials are also applicable to the present disclosure. In the present disclosure, the first light-adjusting element 16a and the second light-adjusting element 16b have different dimensions. In the present disclosure, the dimension is width, length, thickness, diameter, area, concentration, or a combination thereof. Different dimensions represent different widths, different lengths, different thicknesses, different diameters, different areas, different concentrations, or combinations thereof. In accordance with some embodiments, on the substrate 12 of the light-emitting module 102, the dimension of the second light-adjusting element 16b on the second light-emitting unit 14b in the second region 12b (for example, the edge region) is smaller than that of the first light-adjusting element 16a on the first light-emitting unit 14a in the first region 12a (for example, the middle region). The dimension of the light-adjusting elements is as defined above and will not be repeated here. For example, the second dimension (i.e. width) of the second light-adjusting element 16b is smaller than the first dimension (i.e. width) of the first light-adjusting element 16a. For example, the fourth dimension (i.e. concentration) of the second light-adjusting element 16b is smaller than the third dimension (i.e. concentration) of the first light-adjusting element 16a. In accordance with some embodiments, the fourth dimension (i.e. concentration) of the second light-adjusting element 16b is equal to the third dimension (i.e. concentration) of the first light-adjusting element 16a, but the sixth dimension (i.e. area) of the second light-adjusting element 16b is smaller than the fifth dimension (i.e. area) of the first light-adjusting element 16a. In accordance with some embodiments, the fourth dimension (i.e. concentration) of the second light-adjusting element 16b is smaller than the third dimension (i.e. concentration) of the first light-adjusting element 16a, and the sixth dimension (i.e. area) of the second light-adjusting element 16b is smaller than the fifth dimension (i.e. area) of the first light-adjusting element 16a. For example, the eighth dimension (i.e. thickness) of the second light-adjusting element 16b is equal to the seventh dimension (i.e. thickness) of the first light-adjusting element 16a, but the sixth dimension (i.e. area) of the second light-adjusting element 16b is smaller than the fifth dimension (i.e. area) of the first light-adjusting element 16a.

In some embodiments, viewed from a cross-sectional view (as shown in FIG. 1), the width W1 of the first light-adjusting element 16a is greater than the width W2 of the second light-adjusting element 16b. In some embodiments, the concentration of the first light-adjusting element 16a is the same as that of the second light-adjusting element 16b, and the width W1 of the first light-adjusting element 16a is greater than the width W2 of the second light-adjusting element 16b. In accordance with some embodiments, the width W1 of the first light-adjusting element 16a may be in a range from about 1.8 mm to about 2.7 mm. The width W2 of the second light-adjusting element 16b may be in a range from about 0.5 mm to about 2.6 mm, for example, in a range from about 1.5 mm to about 2.6 mm. In accordance with some embodiments, the width of the first light-adjusting element 16a may be greater than the width of the first light-emitting unit 14a, so as to completely cover the first light-emitting unit 14a below. The width of the second light-adjusting element 16b may be greater than the width of the second light-emitting unit 14b, so as to completely cover the second light-emitting unit 14b below. In some embodiments, as shown in FIG. 1, the ratio (%) of the area A2 of the second light-emitting element 16b to the area A1 of the first light-emitting element 16a may be in a range from about 3% to about 95%. For example, it may be in a range from about 20% to about 90%, for example, in a range from about 50% to about 90%, for example, in a range from about 65% to about 90%.

In some embodiments, the light-adjusting layer 16 may include a circular shape, but the present disclosure is not limited thereto, and other suitable shapes of the light-adjusting layer are also applicable to the present disclosure. In some embodiments, viewed from a top view (as shown in FIG. 2A), the light-adjusting layer 16 is circular. In the embodiment shown in FIG. 2A, the concentration of the first light-adjusting element 16a and the concentration of the second light-adjusting element 16b may be the same. The diameter D1 of the first light-adjusting element 16a is larger than the diameter D2 of the second light-adjusting element 16b. In accordance with some embodiments, the diameter D1 of the first light-adjusting element 16a may be in a range from about 1.8 mm to about 2.7 mm. The diameter D2 of the second light-adjusting element 16b may be in a range from about 0.5 mm to about 2.6 mm, for example, in a range from about 1.5 mm to about 2.6 mm. In accordance with some embodiments, the diameter D1 of the first light-adjusting element 16a may be larger than the width of the first light-emitting unit 14a, so as to completely cover the first light-emitting unit 14a below. The diameter D2 of the second light-adjusting element 16b may be larger than the width of the second light-emitting unit 14b, so as to completely cover the second light-emitting unit 14b below.

Referring to FIG. 2B, in accordance with one embodiment of the present disclosure, an electronic device 100 is provided. FIG. 2B is a top view of the electronic device 100.

The structure, dimension, and material composition of some components in the electronic device 100 shown in FIG. 2B are similar to those of the electronic device 100 shown in FIG. 2A, and will not be repeated here. The main difference from FIG. 2A is that, in FIG. 2B, the diameter D1 of the first light-adjusting element 16a is the same as the diameter D2 of the second light-adjusting element 16b, and the concentration of the first light-adjusting element 16a is different from that of the second light-adjusting element 16b. In FIG. 2B, different concentrations are represented by different shadings. In accordance with some embodiments, the concentration of the first light-adjusting element 16a is greater than the concentration of the second light-adjusting element 16b. In the present disclosure, the light-adjusting elements with different concentrations may be produced by screen printing using light-adjusting materials (such as ink). For example, the first light-adjusting element 16a with higher concentration is produced by the first screen printing, and then the second light-adjusting element 16b with lower concentration is produced by the second screen printing.

Referring to FIG. 2C, in accordance with one embodiment of the present disclosure, an electronic device 100 is provided. FIG. 2C is a top view of the electronic device 100.

The structure, dimension, and material composition of some components in the electronic device 100 shown in FIG. 2C are similar to those of the electronic device 100 shown in FIG. 2A, and will not be repeated here. The main difference from FIG. 2A is that, in FIG. 2C, the diameter D1 of the first light-adjusting element 16a is different from the diameter D2 of the second light-adjusting element 16b, and the concentration of the first light-adjusting element 16a is different from that of the second light-adjusting element 16b. In FIG. 2C, different concentrations are represented by different shadings. In some embodiments, the diameter D1 of the first light-adjusting element 16a is greater than the diameter D2 of the second light-adjusting element 16b, and the concentration of the first light-adjusting element 16a is greater than that of the second light-adjusting element 16b. For the suitable diameter range of the light-adjusting elements, reference may be made to the foregoing content, and details are not repeated here. For the suitable area ratio range of the second light-adjusting element 16b to the first light-adjusting element 16a, reference may be made to the foregoing content, and details are not repeated here.

Referring to FIG. 2D, in accordance with one embodiment of the present disclosure, an electronic device 100 is provided. FIG. 2D is a top view of the electronic device 100.

The structure, dimension, and material composition of some components in the electronic device 100 shown in FIG. 2D are similar to those of the electronic device 100 shown in FIG. 2A, and will not be repeated here. The main difference from FIG. 2A is that, in FIG. 2D, the second light-adjusting elements 16b may be divided into a first group G1 and a second group G2, but the present disclosure is not limited thereto, and other suitable group numbers are also applicable to the present disclosure. In FIG. 2D, compared with the second group G2, the first group G1 is closer to the first light-adjusting element 16a, and the second group G2 surrounds the first group G1. In detail, the first light-adjusting element 16a is disposed in the first region 12a, the second light-adjusting element 16b is disposed in the second region 12b, and the first group G1 is closer to the first region 12a. As shown in FIG. 2D, the concentration of the first light-adjusting element 16a, the concentration of the second light-adjusting element 16b in the first group G1, and the concentration of the second light-adjusting element 16b in the second group G2 are the same. In accordance with some embodiments, the diameter D1 of the first light-adjusting element 16a is larger than the diameter D21 of the second light-adjusting element 16b in the first group G1, and larger than the diameter D22 of the second light-adjusting element 16b in the second group G2.

In accordance with some embodiments, as shown in FIG. 2D, the dimension of the first light-adjusting element 16a may be larger than the dimension of the second light-adjusting element 16b in the first group G1. The dimension of the second light-adjusting elements 16b in the first group G1 may be larger than the dimension of the second light-adjusting elements 16b in the second group G2. For example, the diameter D1 of the first light-adjusting element 16a is larger than the diameter D21 of the second light-adjusting element 16b in the first group G1. The diameter D21 of the second light-adjusting elements 16b in the first group G1 is larger than the diameter D22 of the second light-adjusting elements 16b in the second group G2. In some embodiments, the area of the second light-adjusting elements 16b in the first group G1 may be larger than the area of the second light-adjusting elements 16b in the second group G2.

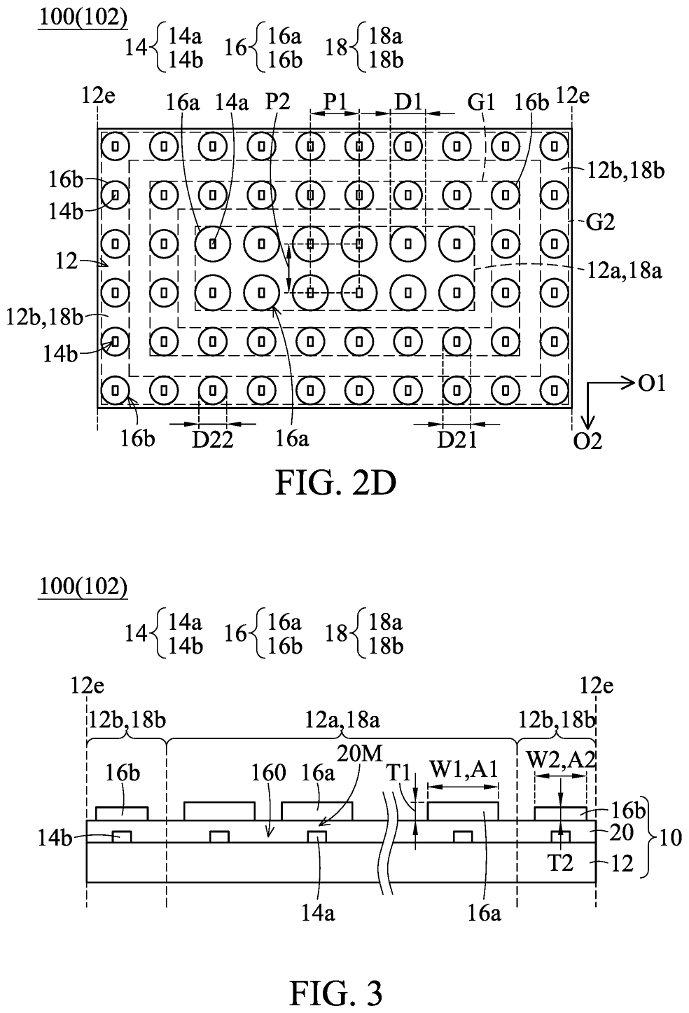

Referring to FIG. 3, in accordance with one embodiment of the present disclosure, an electronic device 100 is provided. FIG. 3 is a cross-sectional view of the electronic device 100.

The structure, dimension, and material composition of some components in the electronic device 100 shown in FIG. 3 are similar to those of the electronic device 100 shown in FIG. 1, and will not be repeated here. The main difference from FIG. 1 is that, in FIG. 3, the concentration of the first light-adjusting element 16a is the same as that of the second light-adjusting element 16b, and the thickness T1 of the first light-adjusting element 16a is greater than the thickness T2 of the second light-adjusting element 16b. In accordance with some embodiments, the thickness T1 of the first light-adjusting element 16a and the thickness T2 of the second light-adjusting element 16b may be in a range from about 0.02 mm to about 0.1 mm, respectively. For example, they may be in a range from about 0.03 mm to about 0.06 mm, for example, in a range from about 0.035 mm to about 0.05 mm. In accordance with some embodiments, the ratio (T2/T1) of the thickness T2 of the second light-adjusting element 16b to the thickness T1 of the first light-adjusting element 16a may be in a range from about 0.3 to about 0.95. For example, it may be in a range from about 0.5 to about 0.9, for example, in a range from about 0.6 to about 0.85.

In some embodiments, the thickness T1 of the first light-adjusting element 16a is the same as the thickness T2 of the second light-adjusting element 16b, and the concentration of the first light-adjusting element 16a is different from the concentration of the second light-adjusting element 16b. In some embodiments, the thickness T1 of the first light-adjusting element 16a is the same as the thickness T2 of the second light-adjusting element 16b, and the concentration of the first light-adjusting element 16a is greater than that of the second light-adjusting element 16b.

In some embodiments, the thickness T1 of the first light-adjusting element 16a is different from the thickness T2 of the second light-adjusting element 16b, and the concentration of the first light-adjusting element 16a is different from that of the second light-adjusting element 16b. In some embodiments, the thickness T1 of the first light-adjusting element 16a is greater than the thickness T2 of the second light-adjusting element 16b, and the concentration of the first light-adjusting element 16a is greater than that of the second light-adjusting element 16b.

Referring to FIG. 4, in accordance with one embodiment of the present disclosure, an electronic device 100 is provided. FIG. 4 is a cross-sectional view of the electronic device 100.

As shown in FIG. 4, the electronic device 100 includes a backlight module 102, a display panel 104, a backplane 40, and a plastic frame 30. The backlight module 102 is disposed on the backplane 40. The display panel 104 is disposed on the backlight module 102. The plastic frame 30 is disposed on the backplane 40 to fix and support the backlight module 102 and the display panel 104. The backlight module 102 includes a light-emitting substrate 10 and an optical film 105. The optical film 105 is disposed on the light-emitting substrate 10. The optical film 105 may be single layer or multilayers. For example, the optical film 105 may be multilayers and may include a first diffusion film 106, a blue-light enhancement film 108, a light-color conversion film 110, a first optical composite film 112, a second diffusion film 114, and a second optical composite film 116, but is not limited thereto. In some embodiments, the light-color conversion film 110 may include a quantum dot (QD) film. In some embodiments, the first optical composite film 112 and the second optical composite film 116 may be composed of the stacks of upper and lower microlens layers, respectively. The display panel 104 includes a first polarizer 118, a first substrate 120, a second substrate 122, a second polarizer 124, and a black matrix 126. In some embodiments, the first substrate 120 may include a thin-film transistor (TFT) substrate. In some embodiments, the second substrate 122 may include a color filter (CF) substrate. In FIG. 4, the light-adjusting layer 16 is disposed between the plurality of light-emitting units 14 and the display panel 104. The optical film 105 is disposed between the substrate 12 and the display panel 104.

In addition, the range where the second light-adjusting element 16b is disposed (for example, the second region 12b of the substrate 12) may correspond to the distance B extending from the edge 126e of the black matrix 126 towards the display region 18. In some embodiments, the distance B of the second region 12b may be in a range from about 0.3 mm to about 50 mm. For example, it may be in a range from about 1 mm to about 30 mm, for example, in a range from about 5 mm to about 20 mm.

In some embodiments, the light-emitting substrate 10 in the backlight module 102 may be replaced by, for example, the light-emitting substrate 10 shown in FIG. 2A, 2B, 2C or 2D.

In FIG. 4, the electronic device 100 further includes a third light-adjusting element 16c disposed in the non-display region 28 and extending towards the display region 18, without exceeding the edge 126e of the black matrix 126. For example, the light-emitting module 102 includes the third light-adjusting element 16c. For example, the third light-adjusting element 16c is disposed on the bottom edge of the second diffusion film 114 in the optical film 105, but the present disclosure is not limited thereto. The third light-adjusting element 16c is also suitable to be disposed at the positions of other film layers in the optical film 105. For example, the third light-adjusting element 16c may be disposed on the bottom edge or the top edge of the first optical composite film 112, the second diffusion film 114, or the second optical composite film 116 in the optical film 105. In some embodiments, the third light-adjusting element 16c is ink, for example, yellow ink, but the present disclosure is not limited thereto, and other suitable inks are also applicable to the present disclosure. In the present disclosure, the excessive blue-light leakage may be balanced by the third light-adjusting element 16c disposed at the edge of the optical film 105. In accordance with some embodiments, the first color of the third light-adjusting element 16c may be different from the second color of the light emitted by the light-emitting unit. For example, the first color may be yellow and the second color may be blue. For example, the first color may be used to balance the second color.

### EXAMPLES

### Examples 1-1-1-4

Measurement (I) of luminance gain of electronic devices

In the examples, the luminance gain was measured using the electronic device 100 shown in FIG. 4. The structural conditions are as follows. The pitch between adjacent light-emitting units was about 4.6 mm. The diameter of the first light-adjusting element was about 1.8 mm. The luminance was measured under different area ratios (A2/A1) of the second light-adjusting element to the first light-adjusting element. In the examples, the light-adjusting element in the second region was the second light-adjusting element 16b. The position for luminance measurement was the central position of the light-emitting unit (e.g., the second light-emitting unit 14b) in the second region shown in FIG. 2A. In the comparative example, the light-adjusting element in the second region shown in FIG. 2A was replaced with the first light-adjusting element 16a.

The measurement results are shown in Table 1. Based on the luminance gain of the comparative example as 100%, the luminance gain under different area ratios (A2/A1) of the second light-adjusting element to the first light-adjusting element in various examples was calculated. The gains are all higher than the difference that can be discerned by human eyes. Moreover, for each example, the graininess and taste observed at the edge 12b (i.e. the second region 12b) are within an acceptable range.

TABLE 1

| | | | Graininess and |
|---|---|---|---|
| Examples/ | | | taste at the edge |
| Comparative | | | 12b (i.e. the |
| Example | A2/A1 | Luminance gain | second region 12b) |
| Comparative | 100% | 100% | Unacceptable |
| Example | | | |
| Example 1-1 | 8% to 10% | 130% to 135% | Acceptable |
| Example 1-2 | 50% to 55% | 115% to 120% | Acceptable |
| Example 1-3 | 65% to 70% | 110% to 115% | Acceptable |
| Example 1-4 | 85% to 90% | 104.5% to 105.0% | Acceptable |

In the examples, the diameter of the first light-adjusting element at the middle position (i.e. the first region) of the substrate was about 1.8 mm. In accordance with Table 1, it can be seen from the above results that, by arranging a light-adjusting element (such as ink) at the edge of the substrate (i.e. the second region), which has a different area from the light-adjusting element in the first region, and properly adjusting the area ratio of the second light-adjusting element located in the second region to the first light-adjusting element located in the first region, the luminance gain presented are all higher than the difference that can be discerned by human eyes. That is, the luminance is significantly improved. By this way, dark bands in the edge region of the substrate can be reduced. In addition, the graininess and taste observed are acceptable.

### Examples 2-1-2-5

### Measurement (II) of Luminance Gain of Electronic Devices

In the examples, the luminance gain was measured using the electronic device 100 shown in FIG. 4. The structural conditions are as follows. The pitch between adjacent light-emitting units was about 5.5 mm. The diameter of the first light-adjusting element was about 2.7 mm. In the examples, the light-adjusting element in the second region was the second light-adjusting element 16b. In the comparative example, the light-adjusting element in the second region shown in FIG. 2A was replaced with the first light-adjusting element 16a. The measuring position was as in Example 1. The measurement results are shown in Table 2. The measured luminance gains are all higher than the difference that can be discerned by human eyes. The graininess and taste observed at the edge 12b (i.e. the second area 12b) are within an acceptable range.

TABLE 2

| | | | Graininess and |
|---|---|---|---|
| Examples/ | | | taste at the edge |
| Comparative | | | 12b (i.e. the |
| Example | A2/A1 | Luminance gain | second region 12b) |
| Comparative | 100% | 100% | Unacceptable |
| Example | | | |
| Example 2-1 | 3.5% to 5.5 | 135% to 140% | Acceptable |
| Example 2-2 | 35% to 40% | 125% to 130% | Acceptable |
| Example 2-3 | 50% to 55% | 115% to 120% | Acceptable |
| Example 2-4 | 70% to 75% | 110% to 115% | Acceptable |
| Example 2-5 | 85% to 90% | 104.5% to 105.0% | Acceptable |

In the examples, the diameter of the first light-adjusting element at the middle position (i.e. the first region) of the substrate was about 2.7 mm. In accordance with Table 2, it can be seen from the above results that, by arranging a light-adjusting element (such as ink) at the edge of the substrate (i.e. the second region), which has a different area from the light-adjusting element in the first region, and properly adjusting the area ratio of the second light-adjusting element located in the second region to the first light-adjusting element located in the first region, the luminance gain presented are all higher than the difference that can be discerned by human eyes. That is, the luminance is significantly improved. By this way, dark bands in the edge region of the substrate can be reduced. In addition, the graininess and taste observed are acceptable.

In summary, in accordance with some embodiments, on the substrate of the light-emitting module, by arranging the first light-adjusting element on the first light-emitting unit in the first region (i.e. the middle region) and the second light-adjusting element on the second light-emitting unit in the second region (i.e. the edge region) with different dimensions, the luminance of the edge region of the substrate can be improved, reducing the loss of light source and dark bands in the edge region of the substrate, and optimizing the taste at the edge of the module.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a light-emitting module, comprising:
a substrate having a first region and a second region, the second region being closer to an edge of the substrate than the first region;
a plurality of light-emitting units disposed on the substrate, wherein the light-emitting units comprise a first light-emitting unit disposed in the first region and a second light-emitting unit disposed in the second region; and
a light-adjusting layer comprising a first light-adjusting element disposed on the first light-emitting unit and a second light-adjusting element disposed on the second light-emitting unit, wherein the first light-adjusting element and the second light-adjusting element have different dimensions.

2. The electronic device as claimed in claim 1, wherein the first light-adjusting element has a first dimension, the second light-adjusting element has a second dimension, and the second dimension is smaller than the first dimension.

3. The electronic device as claimed in claim 1, wherein the dimension is width, length, thickness, diameter, area, concentration, or a combination thereof.

4. The electronic device as claimed in claim 1, wherein the second light-adjusting element has a smaller width than the first light-adjusting element.

5. The electronic device as claimed in claim 1, wherein the second light-adjusting element has less thickness than the first light-adjusting element.

6. The electronic device as claimed in claim 5, wherein the first light-adjusting element has a concentration equal to that of the second light-adjusting element.

7. The electronic device as claimed in claim 5, wherein the second light-adjusting element has a smaller concentration than that of the first light-adjusting element.

8. The electronic device as claimed in claim 1, wherein the second light-adjusting element has a smaller concentration than that of the first light-adjusting element.

9. The electronic device as claimed in claim 8, wherein the first light-adjusting element has a thickness equal to that of the second light-adjusting element.

10. The electronic device as claimed in claim 8, wherein the first light-adjusting element has an area equal to that of the second light-adjusting element.

11. The electronic device as claimed in claim 1, wherein the second light-adjusting element has a smaller area than the first light-adjusting element.

12. The electronic device as claimed in claim 11, wherein the first light-adjusting element has a thickness equal to that of the second light-adjusting element.

13. The electronic device as claimed in claim 11, wherein the first light-adjusting element has a concentration equal to that of the second light-adjusting element.

14. The electronic device as claimed in claim 11, wherein the second light-adjusting element has a smaller concentration than that of the first light-adjusting element.

15. The electronic device as claimed in claim 1, wherein the light-adjusting layer is ink.

16. The electronic device as claimed in claim 1, wherein the first light-adjusting element has a greater width than the first light-emitting unit, and the second light-adjusting element has a greater width than the second light-emitting unit.

17. The electronic device as claimed in claim 1, further comprising an encapsulation layer, wherein at least part of the encapsulation layer is disposed between the light-emitting units and the light-adjusting layer.

18. The electronic device as claimed in claim 1, further comprising a display panel, wherein the light-adjusting layer is disposed between the light-emitting units and the display panel.

19. The electronic device as claimed in claim 18, wherein the display panel has a display region and a non-display region, and the first region and the second region of the light-emitting module correspond to the display region of the display panel.

20. The electronic device as claimed in claim 19, further comprising a third light-adjusting element disposed in the non-display region.
